(19) United States
(12) Patent Application Publication
(10) Pub. No.: US 2010/0241922 A1
(43) Pub. Date: Sep. 23, 2010

(54) ERROR CORRECTION CIRCUIT AND DATA STORAGE DEVICE

(75) Inventors: Kana FURUHASHI, Kawasaki-shi (JP); Akihiro YAMAZAKI, Yokohama-shi (JP)

Correspondence Address: KNOBBE MARTENS OLSON & BEAR LLP, 2040 MAIN STREET, FOURTEENTH FLOOR, IRVINE, CA, 92614, US

(73) Assignee: TOSHIBA STORAGE DEVICE CORPORATION, Tokyo (JP)

(21) Appl. No.: 12/725,321

(22) Filed: Mar. 16, 2010

(30) Foreign Application Priority Data
Mar. 17, 2009 (JP) 2009-064270

(51) Int. Cl. H03M 13/05; G06F 11/10

(52) U.S. Cl. 714/752; 714/E11.032

(57) ABSTRACT

According to one embodiment, a circuit includes: an ECC encoder to assign symbols of a data string to M interleaves in sequence, create redundancy symbols for each interleaved string, insert the redundancy symbol into the data string every N symbols of the data string, and create ECC encoded data, where M and N are greater than or equal to 2; and an ECC decoder to assign the symbols of the data string that has been inserted with the redundancy symbols to M interleaves and apply error correction to each assigned string, using the redundancy symbols of that assigned string. The encoder assigns each symbol of the data string that corresponds to an insertion position of the different one of the redundancy symbols in the data string to a next position next to and skipping an in-sequence interleaving position of that symbol, and creates the redundancy symbols for each interleaved string.

### CROSS-REFERENCE TO RELATED APPLICATIONS

This application is based upon and claims the benefit of priority from Japanese Patent Application No. 2009-064270, filed Mar. 17, 2009, the entire contents of which are incorporated herein by reference.

### BACKGROUND

1. Field

One embodiment of the invention relates to an error correction circuit and a data storage device, which create an error correction code (ECC) for an interleaved data string and add the error correction code (ECC) to the data string.

2. Description of the Related Art

In the area of signal reproduction, an error correction technique is of increasing importance. Especially, an error correction method using an error correction code (ECC) is widely used. For example, in a hard disk drive (HDD), when data is written in a disk medium, an ECC redundancy symbol is created from the data, added to the data, and a data string added with the ECC redundancy symbol is written.

At that time, in the magnetic recording, constraint conditions are provided for a code. For example, run length limited (RLL) constraint length is provided. Therefore, in order to comply with the RLL constraint length, a method of inserting the ECC redundancy symbol into RLL encoded data is used.

In general, when the length of a correction code word exceeds the correctable code length of the ECC, correction is performed using interleaving. The main purpose of interleaving of the ECC in the HDD is to distribute a burst error to each interleave, and a method of assigning data to be written in a disk medium, to each interleave in sequence is used.

FIG. 8 is an explanatory view of an ECC encoding method in conventional interleaving. In the example of FIG. 8, four interleaves are provided, and the redundancy symbol is inserted every 8 symbols.

In FIG. 8, the numbers in blocks of data 100 are symbol numbers. For example, the data 100 is constituted of 3300 symbols. When four interleaves are provided, the symbols of the data 100 are assigned to four interleaves in sequence. The redundancy symbols of the ECC are generated in the horizontal direction of FIG. 8 for each of the four interleave blocks 102.

For example, the redundancy symbols P1-1, P1-2, . . . , and P1-32 are generated for interleave 1, the redundancy symbols P2-1 to P2-32 are generated for interleave 2, the redundancy symbols P3-1 to P3-32 are generated for interleave 3, and the redundancy symbols P4-1 to P4-32 are generated for interleave 4.

The generated redundancy symbol is inserted into a position of the ninth symbol every 8 symbols of the original data string 100. Thus, a data string 106 that has been inserted with the ECC redundancy symbols every 8 symbols of the original data string 100 is obtained. The data string is recorded in a disk medium.

By the interleaving, a different ECC redundancy symbol is given every 4 data symbols. Therefore, when a burst error occurs, for example, when the burst error occurs in the data symbols D1 to D8, the error is distributed to each interleave, and correction is possible using the ECC redundancy symbols of the interleaves.

For example, Japanese Patent Application Publication (KOKAI) No. 2006-031825 discloses such ECC encoding using a plurality of interleaves.

Conventionally, the ECC redundancy symbols are generated for each interleave and thereafter inserted in user data. Therefore, a position of an interleaved data block is deviated in a data string, and the dispersion to the interleaves may be uneven. Consequently, there may be a part where symbols belonging to the same interleave are continuously written in a disk medium, and when a burst error occurs, the error may be concentrated in the same interleave.

For example, in a data string 110 of FIG. 9, the ECC redundancy symbol P1-1 and the data symbol D9, which belong to the same interleave, are continuous. If a burst error illustrated by the arrow occurs, in an interleave block 112, two errors exist in the interleave 1, one error in interleave 2, no error in interleave 3, and one error in interleave 4. Thus, the errors are not evenly distributed.

### BRIEF DESCRIPTION OF THE SEVERAL VIEWS OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary external view of a data storage device according to an embodiment of the invention;

FIG. 2 is an exemplary block diagram of a recording and reproducing system of the data storage device according to an embodiment of the invention;

FIG. 3 is an exemplary explanatory view of ECC encoding according to an embodiment of the invention;

FIG. 4 is an exemplary explanatory view of correction when a burst error occurs in the embodiment of FIG. 3;

FIG. 5 is an exemplary block diagram of an ECC encoder of FIG. 2;

FIG. 6 is an exemplary block diagram of an ECC decoder of FIG. 2;

FIG. 7 is an exemplary block diagram of an ECC correction circuit of FIG. 6;

FIG. 8 is an exemplary explanatory view of the conventional ECC encoding method using interleaving; and

FIG. 9 is an exemplary explanatory view of correcting capability of the conventional ECC encoding method.

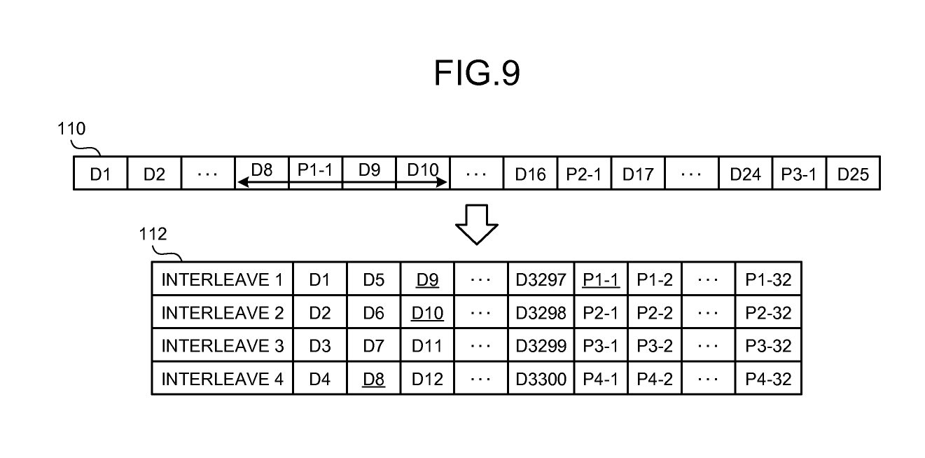

### DETAILED DESCRIPTION

Various embodiments according to the invention will be described hereinafter with reference to the accompanying drawings. In general, according to one embodiment of the invention, an error correction circuit comprises: an ECC encoder configured to assign data symbols of a data string to interleaving positions of M interleaves in interleaving sequence to form M interleaved data strings, create redundancy symbols for each of the M interleaved data strings, insert a different one of the created redundancy symbols into the data string every N data symbols of the data string, and create ECC encoded data, wherein M is greater than or equal to 2 and N is also greater than or equal to 2; and an ECC decoder configured to assign the data symbols of the data string that has been inserted with the redundancy symbols to interleaving positions of M interleaves to form M assigned data strings and apply error correction to each of the M assigned data strings, using the redundancy symbols of that assigned data string, wherein the ECC encoder is further configured to assign each data symbol of the data string that corresponds to an insertion position of the different one of the created redundancy symbols in the data string to a next interleaving position next to and skipping an in-sequence interleaving position of that data symbol, the in-sequence interleaving position being in accordance with the interleaving sequence, and create the redundancy symbols for each interleaved data string.

According to another embodiment of the invention, a data storage device comprises: an ECC encoder configured to assign data symbols of a data string to interleaving positions of M interleaves in interleaving sequence to form M interleaved data strings, create redundancy symbols for each of the M interleaved data strings, insert a different one of the created redundancy symbols into the data string every N data symbols of the data string, and create ECC encoded data, wherein M is greater than or equal to 2 and N is also greater than or equal to 2; a recording unit configured to record the ECC encoded data from the ECC encoder in a recording medium; a reading unit configured to read the data string that has been inserted with the redundancy symbols from the recording medium; and an ECC decoder configured to assign the data symbols of the read data string that has been inserted with the redundancy symbols to interleaving positions of M interleaves to form M assigned data strings and apply error correction to each of the M assigned data strings, using the redundancy symbols of that assigned data string, wherein the ECC encoder is further configured to assign each data symbol of the data string that corresponds to an insertion position of the different one of the created redundancy symbols in the data string to a next interleaving position next to and skipping an in-sequence interleaving position of that data symbol, the in-sequence interleaving position being in accordance with the interleaving sequence, and create the redundancy symbols for each interleaved data string.

Hereinafter, embodiments of the invention will be described in order of a data storage device, ECC encoding, ECC encoding and decoding configurations, and other embodiments.

(Data Storage Device)

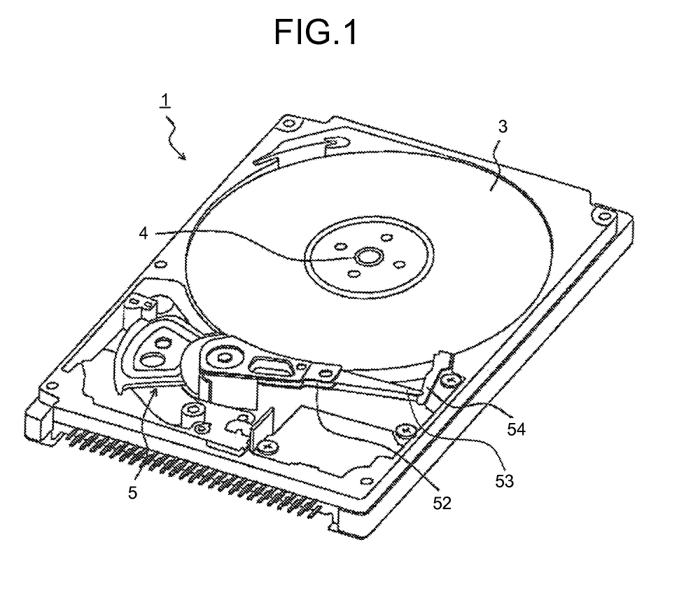

FIG. 1 is an external view of a data storage device according to one embodiment of the invention. FIG. 1 illustrates a magnetic disk device (a hard disk drive) as an example of the data storage device. As illustrated in FIG. 1, a disk enclosure (hereinafter referred to as “DE”) 1 stores components of the magnetic disk device. In the DE 1, a magnetic disk 3 which is a magnetic recording medium is fitted around the rotation shaft of a spindle motor 4.

The spindle motor 4 mounted on the DE 1 rotates the magnetic disk 3. An actuator (hereinafter referred to as “VCM”) 5 rotates an arm (hereinafter referred to as “head actuator”) 52. The arm 52 comprises a suspension, and a magnetic head 53 is provided at the end of the suspension of the arm 52. Thus, the VCM 5 moves the magnetic head 53 in the radial direction of the magnetic disk 3. The actuator 5 comprises a voice coil motor (VCM) rotating around a rotation shaft.

In FIG. 1, the one magnetic disk 3 is mounted on the magnetic disk device, and the two magnetic heads 53 are simultaneously driven by the same actuator 5. The magnetic head 53 comprises a read element comprising a magnetoresistive (MR) element and superposed on a slider, and a write element comprising a write coil and superposed on the read element.

The magnetic disk 3 comprises on the outside a ramp mechanism 54 for retracting the magnetic head 53 from the magnetic disk 3 and parking the magnetic head 53.

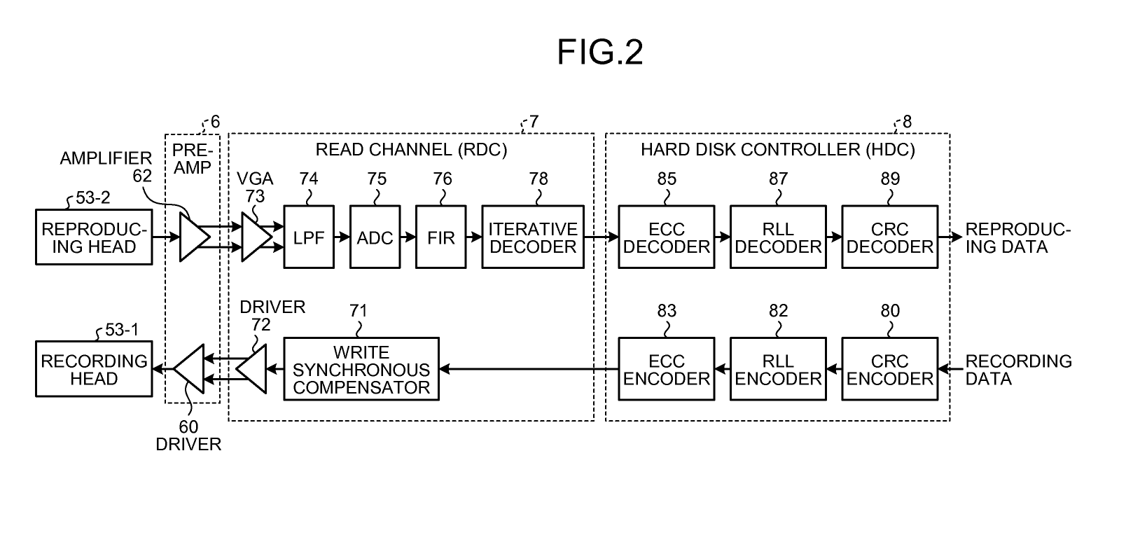

Further, the DE 1 of FIG. 1 comprises in its lower portion a printed circuit assembly (control circuit module). The printed circuit assembly comprises a hard disk controller (HDC), a microcontroller (MCU), a read/write channel circuit (RDC), a servo control circuit, a data buffer (RAM), and a read only memory (ROM) to be described in FIG. 2 and the following figures.

FIG. 2 is a circuit block diagram of a main part of a recording and reproducing system according to one embodiment of the invention. As illustrated in FIG. 2, the recording and reproducing system of the magnetic disk device roughly comprises a hard disk controller (HDC) 8, a read channel (RDC) 7, and a preamp 6.

The recording system will be first described. A recording data string is input to the HDC 8. In the HDC 8, a CRC encoder 80 creates a cyclic redundancy code (CRC) from recording data to add the created CRC to the recording data string. A recording (RLL) encoder 82 converts the recording data string added with the CRC into a string satisfying the constraint conditions such as a run length limited (RLL) code. An ECC encoder 83 adds the redundancy symbols of an error correction code (ECC) to the data string output from the recording encoder 82.

The data string output from the ECC encoder 83 of the HDC 8 is input to the RDC 7. In the RDC 7, a write synchronous compensator 71 compensates the output data string in synchronization with a write clock. The data string subjected to the write synchronous compensation is amplified to the recording data string by a driver 72 and output to the preamp 6.

In the preamp 6, a driver 60 generates a write current to a recording head 53-1 in accordance with the recording data string.

The reproducing system will now be described. An analog voltage from a reproducing head 53-2 is amplified by an amplifier 62 of the preamp 6 and thereafter output to the RDC 7. In the RDC 7, an amplified analog signal is converted into a digital signal through a variable gain amp (VGA) 73, a low-pass filter (LPF) 74, and analog-digital converter (ADC) 75.

After a finite impulse response (FIR) filter 76 performs PR waveform equalization, an iterative decoder 78 such as a Viterbi detector performs maximum-likelihood decoding.

A decoding bit string output from the iterative decoder 78 is input to an ECC decoder 85 of the HDC 8. The ECC decoder 85 performs error correction, using a Reed-Solomon (RS) code. When the ECC decoding is successfully performed, the data string output from the ECC decoder 85 is output as reproduction data through a recording (RLL) decoder 87 and a CRC decoder 89.

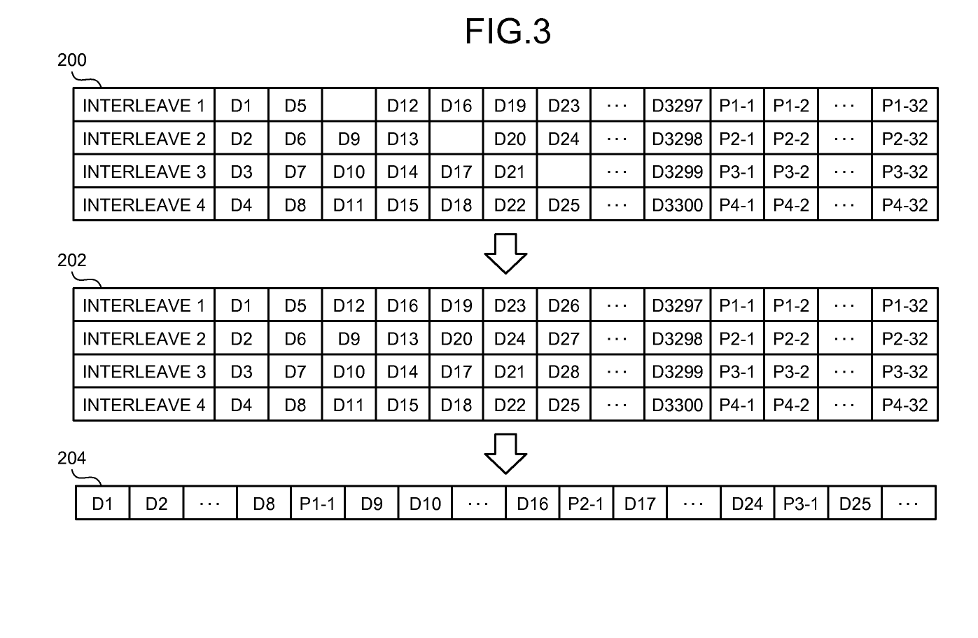

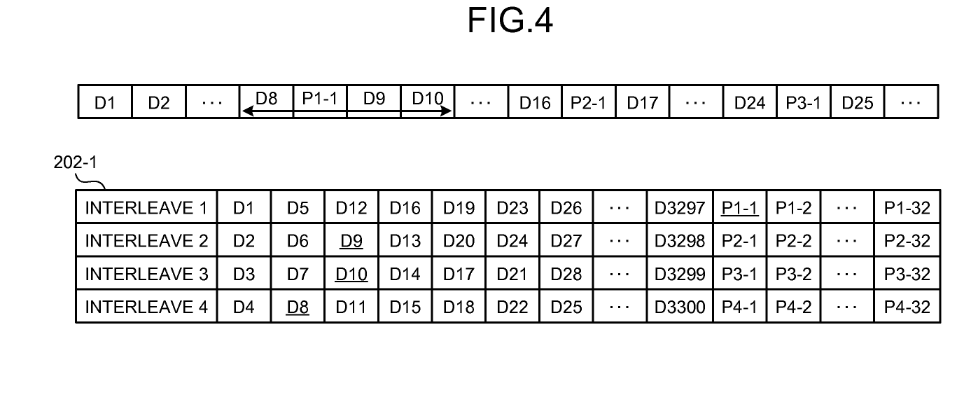

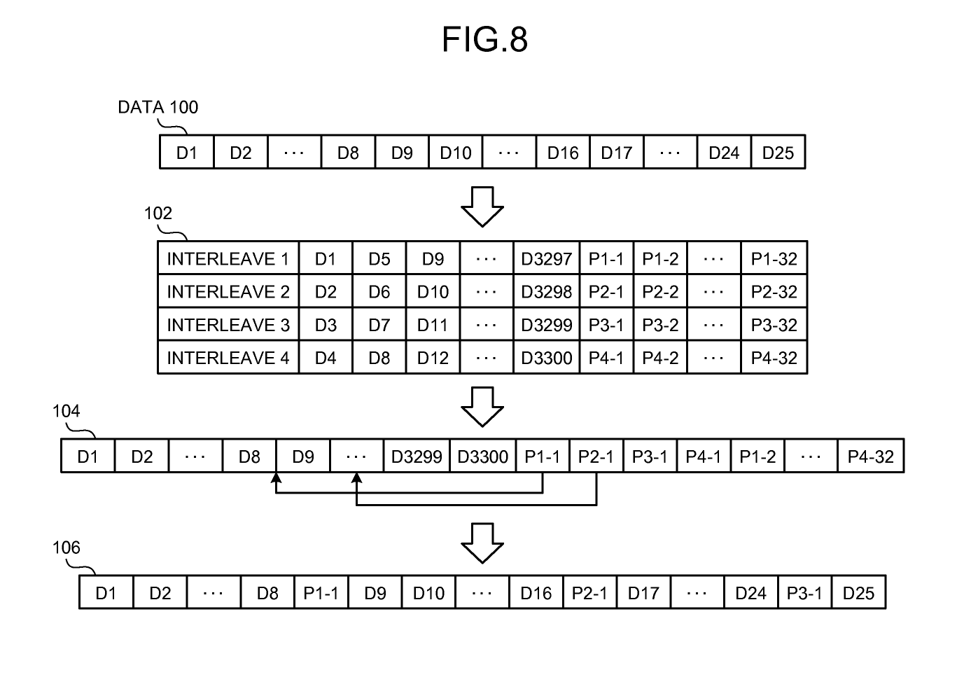

FIG. 3 is an explanatory view of encoding performed by the ECC encoder 83 of FIG. 2. FIG. 4 is an explanatory view of a correction operation for a burst error in encoded data of FIG. 3. In FIG. 3, the data string 100 similar to that of FIG. 8 is interleaved into four, and the redundancy symbol is inserted every 8 symbols.

The generation of the ECC redundancy symbols is first described. In order to generate the redundancy symbols, upon data input, for each input of one data symbol, a redundancy symbol (ECC) generation circuit increases an interleave number, to which the data is input, by “1”. When the interleave number reaches M (in FIG. 3, M is “4”), it returns to the interleave having the interleave number “1”. Such operation is repeated. However, at where a redundancy symbol is inserted, the interleave is skipped. Therefore, when the input data is a multiple of (N−1) symbols (in FIG. 3, N=9), the interleave number to which that data is input next is increased by “2”. Consequently, one interleave to which a symbol of the data string encoded by RLL belong is skipped every (N−1) symbols between the data head and the last part into which the final redundancy symbol is inserted.

The details are described in FIG. 3. The ECC generation circuit generates 32 redundancy symbols for each interleave in a horizontal direction of an interleave block 200 of FIG. 3. Namely, 128 symbols are generated in four interleaves. In the interleave block 200, (9×L)-th (L=1, 2, 3, . . . , and 128) symbol positions are left free for the ECC redundancy symbols, and therefore, the ECC redundancy symbol generation circuit skips one interleave every 8 symbols, up to the 8×128=1024th symbol. For example, a data symbol D9 is input not to the interleave with the interleave number “1” (interleave 1) but to the interleave with the interleave number “2” (interleave 2), and a data symbol D17 is input not to interleave 2 but to interleave 3.

In the ECC redundancy symbol generation circuit, in the interleave block, the skipped positions are filled in by data shifting to the left, and therefore, the interleave block 200 illustrating a correspondence between each interleave and the data symbols becomes a block 202 in which the data symbols are shifted to the left, and this means the redundancy symbols are generated in the horizontal direction of the interleave block 202. Namely, the interleave 1 generates the redundancy symbols from the data symbols D1, D5, D12, and so on.

Next, the insertion of the redundancy symbols is described. In the generation of the redundancy symbols, an interleave to which a symbol of the input data belongs is skipped every (N−1) symbols, and therefore, the redundancy symbols belonging to the skipped interleaves are inserted into the insertion positions in sequence, symbol by symbol.

If “I” represents integers from “1” to “T” (T is a total number of redundancy symbols), the interleave number of the skipped interleave is I×N % M, which is a remainder of ((I×N)/M), in sequence from the beginning of data (however, when (I×N) % M=0, the interleave number of the skipped interleave is M). Namely, the redundancy symbol of (I×N % M)-th interleave is inserted every (N−1) symbols.

In FIG. 3, since N=9, M=4, an input data format 204 to the RDC is created as follows. When I=1, (I×N % M)=9% 4=1, and therefore, the redundancy symbol P1-1 in the interleave 1 is inserted at the N=9-th insertion part of the input data format 204. When I=2, 18% 4=2, and therefore, the redundancy symbol P2-1 in interleave 2 is inserted at the N×2=18-th. When I=3, 27% 4=3, and therefore, the redundancy symbol P3-1 in interleave 3 is inserted at the N×3=27-th. When I=4, 36% 4=0, and therefore, the redundancy symbol P4-1 in interleave 4 is inserted at the 36th. “0” is treated as “4”.

When data is read, and when ECC decoding is performed, the inserted (I×N)-th (I=1 to the total number of redundancy symbols) redundancy symbol is returned to the (I×N % M)-th (when I×N % M=0, the M-th) interleave. Thereafter, as in the generation of the redundancy symbols, the next interleave is skipped every (N−1) symbols between the head data and the last part into which the final redundancy symbol is inserted, and a syndrome of each interleave is generated. When there is an error, normal ECC correction is performed.

As described above, in the recording system, as illustrated in FIG. 3, the redundancy symbols of each interleave are inserted into the blanks left free in the interleave block, and transmission is performed in sequence of the data string 204 of FIG. 3. Therefore, in a data string of FIG. 4, when a burst error illustrated by the arrow occurs, as illustrated in the corresponding interleave block 202-1 of FIG. 4, each interleave has one error, and thus are well distributed. Namely, the underlined parts in the interleave block 202-1 of FIG. 4 correspond to the burst error, and the interleaves 1 to 4 each have one error.

As described above, the interleaves into which the redundancy symbols are inserted are skipped in advance to generate the redundancy symbols. Thereafter, the redundancy symbols corresponding to the skipped positions are inserted in sequence. Accordingly, the arrangement of interleaves for data to be recorded in a medium is uniformly distributed. Also upon decoding, a syndrome is generated in the same order as the order of the generation and correction is performed.

(ECC Encoding and Decoding Configuration)

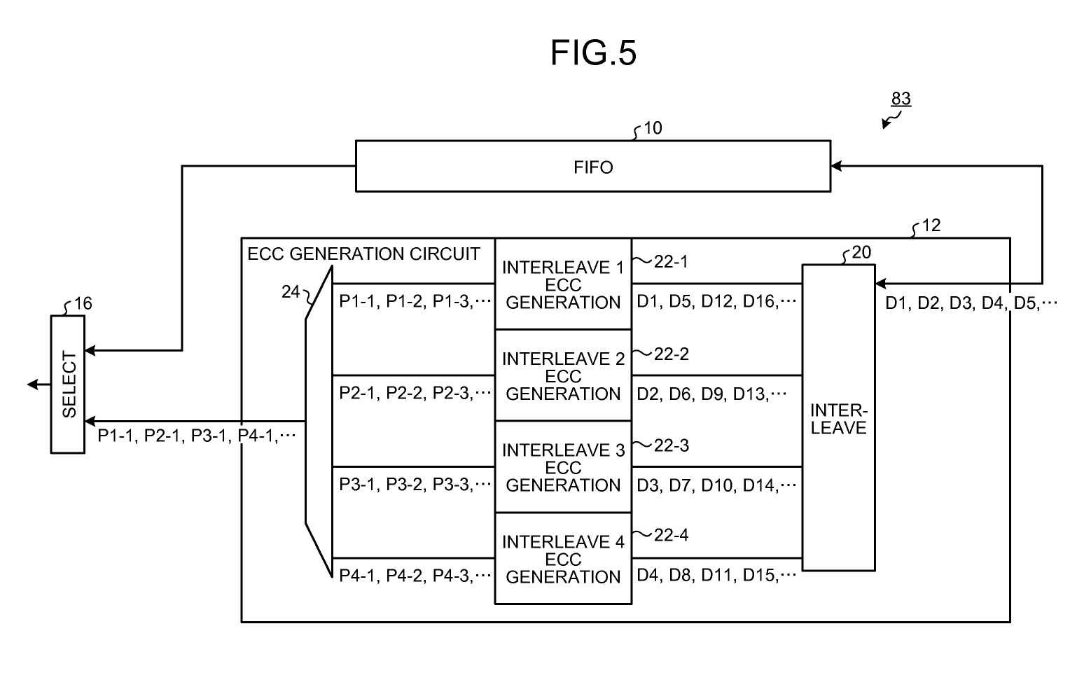

Next, the ECC encoding and decoding configuration is described. FIG. 5 is a block diagram of the ECC encoder 83 of FIG. 2. In FIG. 5, the ECC encoder 83 comprises a first-in-first-out (FIFO) memory 10, an ECC generation circuit 12, and a selector 16.

The RLL encoded data string (sector data) is input to the FIFO memory 10 and the ECC generation circuit 12 in parallel. The ECC generation circuit 12 completes the generation of the ECC redundancy symbols when input of all sector data is finished. After the all sector data is input to the FIFO memory 10 and the ECC generation circuit 12, the selector 16 inserts an ECC parity from the ECC generation circuit 12 every 8 symbols of the sector data output from the FIFO memory 10 and outputs a data string.

The ECC generation circuit 12 comprises an interleave circuit 20, ECC generation circuits 22-1 to 22-4 of the interleaves 1 to 4 and a selector 24. The RLL encoded data string is input to the interleave circuit 20 in order of D1, D2, D3, and so on. The interleave circuit 20 assigns the data string, input in that order, to the ECC generation circuits 22-1 to 22-4 of the interleaves 1 to 4 in a sequence different from the conventional sequence and, as described above, an interleave to be input is skipped for each input of 8 symbols of data up to the 1024th symbol.

The ECC generation circuits 22-1 to 22-4 of the interleaves 1 to 4 generate the ECC parities from the input data symbols. For example, the ECC generation circuits 22-1 to 22-4 generate the ECC parities P1-1, P1-2, P1-3, and so on from the input data symbols D1, D5, D12, D16, and so on.

The selector 24 selects the ECC parities from the ECC generation circuits 22-1 to 22-4 of the interleaves 1 to 4 in the sequence of the interleave numbers of the interleaves and outputs the ECC parities in order of P1-1, P2-1, P3-1, and P4-1.

In this way, the ECC-encoded data string as described in FIG. 3 is obtained.

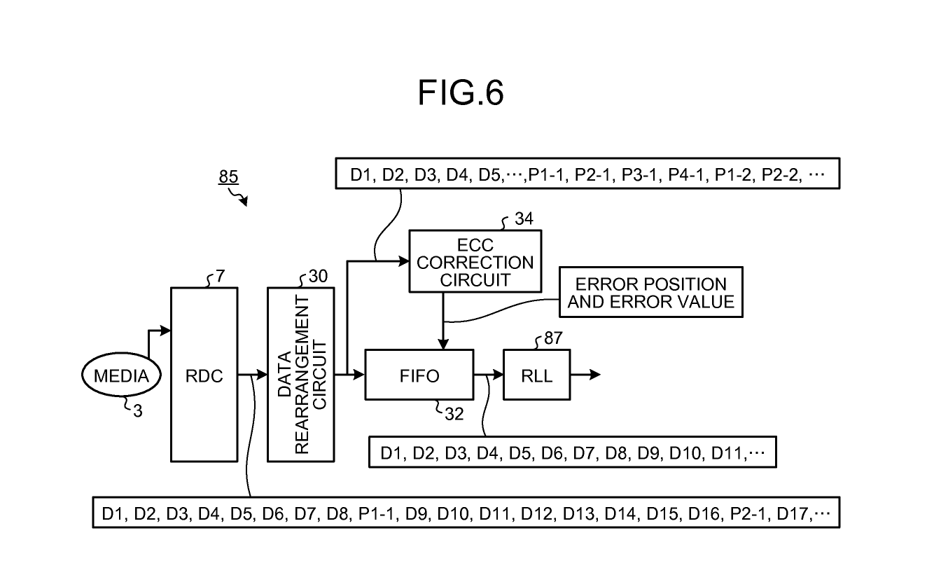

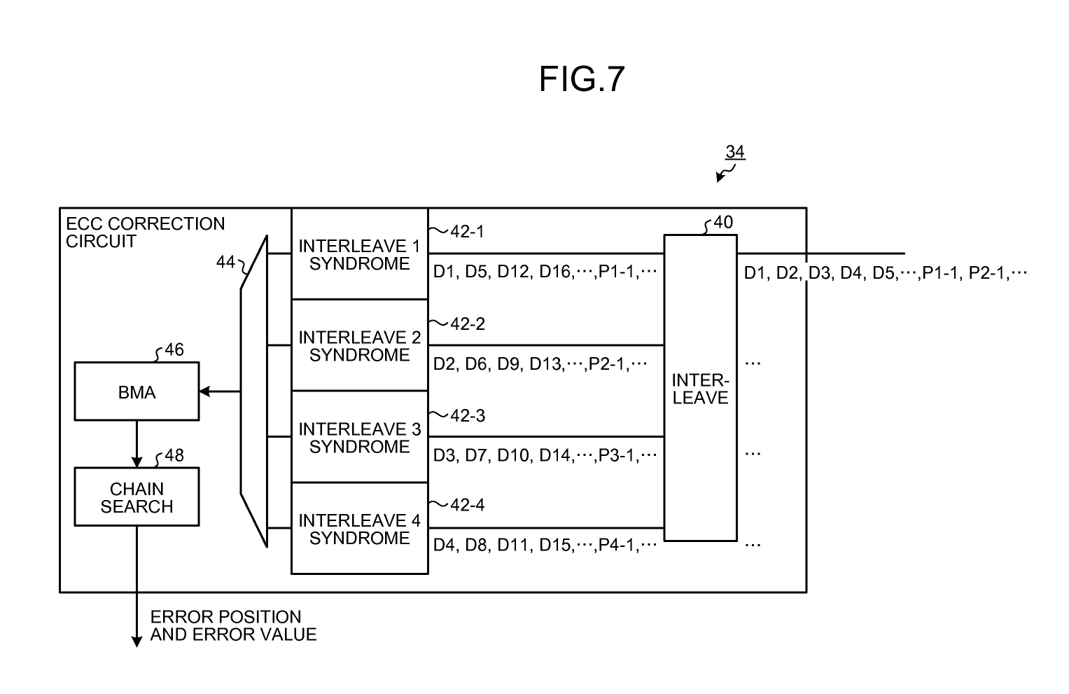

Next, the ECC decoding configuration is described. FIG. 6 is a block diagram of the ECC decoder 85 of FIG. 2. FIG. 7 is a block diagram of an ECC correction circuit of FIG. 6.

As illustrated in FIG. 6, the ECC decoder 85 is constituted of a data rearrangement circuit 30, a FIFO memory 32, and an ECC correction circuit 34.

The data rearrangement circuit 30 receives sector data, read from the magnetic disk 3, from the RDC 7 (see, FIG. 2). The data rearrangement circuit 30 extracts the ECC parities from the data string added with the ECC parity every 8 data symbols and places the ECC (redundancy symbol) parities P1-1, P2-1, P3-1, P4-1, P2-1, P2-2, and so on after the data symbol sequence D1, D2, and so on.

The replaced data string is stored in the FIFO memory 32, and, at the same time, input to the ECC correction circuit 34. The ECC correction circuit 34 generates an ECC syndrome from the data symbol string and the ECC redundancy symbols to obtain an error position. The ECC correction circuit 34 then applies error correction to the data symbols in the FIFO memory 32. When the correction is complete, the data symbol sequence D1, D2, D3, and so on is output from the FIFO memory 32 to the RLL decoder 87. The output data string is decoded by the RLL decoder 87.

Based on FIG. 7, the ECC correction circuit 34 is described. The ECC correction circuit 34 has an interleave circuit 40, syndrome calculating circuits 42-1 to 42-4 of the interleaves 1 to 4, a selector 44, and a BMA (calculator in a Berlekamp Massey method) 46, and a chain search execution circuit 48.

The interleave circuit 40 receives a data symbols D1, D2, and so on and ECC redundancy symbols P1-1, P2-1, P3-1, and so on from the data rearrangement circuit 30 in sequence. The interleave circuit 40 assigns the data symbols to the syndrome calculating circuits 42-1 to 42-4 of the interleaves 1 to 4 in a sequence different from the conventional sequence, up to the 1024th symbol, skipping one interleave for each input of 8 data symbols. Since the ECC redundancy symbols P1-1, and so on are arranged in order, no interleave is skipped, and assigning is performed.

The syndrome calculating circuits 42-1 to 42-4 of the interleaves 1 to 4 calculate syndrome polynomials (coefficients of the polynomial are s1, s2, and so on) of the data string from the input data string. In this way, all data symbols and ECC redundancy symbols are input, and the syndrome of each interleave is determined.

A BMA (error position polynomial calculator) 46 calculates an error position polynomial from the syndrome polynomial, using the Berlekamp Massey method. In the Berlekamp Massey method, as is well known, starting from an initial value of a polynomial, the polynomial is repeatedly updated the number of times equal to the order of a generator polynomial, whereby the error position polynomial is calculated.

The BMA 46 receives the calculated syndromes from the syndrome calculating circuits 42-1 to 42-4 of the interleaves 1 to 4 through the selector 44 to calculate the error position polynomial, and, thus, to determine whether or not an error exists within a range of correcting capability of the ECC.

The chain search execution circuit 48 performs chain search to obtain the error position of the interleave that has been determined, in the BMA 46, to have an error. When the error position is specified by the chain search, an error value is calculated.

The error position and the error value are used to correct the data symbol at the corresponding position in the FIFO memory 32. In this way, as described in FIG. 4, the error correction on the data symbols is performed.

### Other Embodiments

In the above embodiment, four ECC interleaves are provided, and the insertion interval is 9 symbols. However, the insertion interval may be 7 symbols. If it is every 7 symbols, for example when the ECC is generated, a position into which the redundancy symbol is first inserted corresponds to the third interleave, the next insertion position corresponds to the second interleave, and the insertion position after the next corresponds to the first interleave; therefore, the sequence of the ECC redundancy symbols to be output is changed. In the ECC correction, since the ECC redundancy symbols are input in order of P3-1, P2-1, P1-1, P4-1, and so on, the ECC redundancy symbols are input to the corresponding interleaves.

In the above embodiment, although the number of interleaves M is four, the invention is effective when the number of interleaves is two or more. It is preferable that the ECC redundancy symbol is inserted with an interval that allows the RLL constraint length of data transmitted to the RDC to be maintained after the insertion of the ECC redundancy symbol.

Further, in the above embodiment, the ECC comprises four interleaves, and the insertion interval N is 9 symbols. However, when the insertion interval N is 8 symbols or 10 symbols, i.e., when the greatest common divisor of the insertion interval N and the number of interleaves M (e.g., M=“4”) is not “1”, the interleaves may be unevenly skipped. Thus, the greatest common divisor of the insertion interval N and the number of interleaves M is preferably “1”.

Furthermore, in the above embodiment, although a recording and reproducing system of a magnetic disk device has been described, the invention is applicable to recording and reproducing systems of other data storage devices such as optical media and semiconductor memories, encoding in communication devices, and demodulation systems of the communication devices.

According to an embodiment of the invention, when a data string is interleaved, data at the insertion position of a redundancy symbol in the data string is assigned to the next interleaving position, skipping an interleaving position according to an interleaving sequence, and the redundancy symbols of a data string in each interleave are generated. Therefore, the interleaving arrangement of the data string is uniformly distributed, and it is possible to improve the correction of burst errors.

The various modules of the systems described herein can be implemented as software applications, hardware and/or software modules, or components on one or more computers, such as servers. While the various modules are illustrated separately, they may share some or all of the same underlying logic or code.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An error corrector, comprising:
an error correction code (ECC) encoder configured to assign data symbols of a data string to interleaving positions of M interleaves in interleaving sequence in order to generate M interleaved data strings, to create redundancy symbols for each of the M interleaved data strings, to insert the created redundancy symbols not corresponding to the M interleaved data strings that the redundancy symbols were created into the data string by every N data symbols of the data string, and to create ECC encoded data, wherein M is greater than or equal to 2 and N is greater than or equal to 2; and
an ECC decoder configured to assign the data symbols of the data string inserted with the redundancy symbols to interleaving positions of M interleaves in order to generate M assigned data strings and to correct errors to each of the M assigned data strings, using the redundancy symbols of the assigned data string,
wherein the ECC encoder is further configured to assign each data symbol of the data string that corresponds to an insertion position the created redundancy symbols not corresponding to the M interleaved data strings that the redundancy symbols were created in the data string to a next interleaving position next to an in-sequence interleaving position of the data symbol, the in-sequence interleaving position being in accordance with the interleaving sequence, and to create the redundancy symbols for each interleaved data string.

2. The error corrector of claim 1, wherein the ECC decoder is further configured to sort the data string inserted with the redundancy symbols in order to generate the data string and the redundancy symbols, to assign each data symbol corresponding to the insertion position of the redundancy symbol to the next interleaving position.

3. The error corrector of claim 1, wherein the greatest common divisor of M and N is “1”.

4. The error corrector of claim 1, wherein the ECC encoder comprises:
a memory configured to store the data string;
an ECC generator configured to assign the data symbols of the data string to the interleaving positions of the M interleaves and to create the redundancy symbols for each of the M interleaved data strings; and
a creator configured to insert the created redundancy symbols not corresponding to the M interleaved data strings that the redundancy symbols were created into the data string every N data symbols of the data string in the memory and to create the ECC encoded data.

5. The error corrector of claim 4, wherein the ECC generator comprises an interleaver configured to assign the data symbols of the data string to the interleaving positions of the M interleaves.

6. The error corrector of claim 2, wherein the ECC decoder comprises:
a sorter configured to sort the data string inserted with the redundancy symbols in order to generate the data string and the redundancy symbols;
a memory configured to store the sorted data string; and
an ECC corrector configured to assign each data symbol corresponding to the insertion position of the redundancy symbol of the sorted data string to the next interleaving position next to the in-sequence interleaving position and to correct errors in each of the M assigned data strings in the memory using the redundancy symbols of the assigned data string.

7. The error corrector of claim 6, wherein the ECC corrector comprises:
an interleaver configured to assign the data symbols of the data string to the interleaving positions of the M interleaves and to assign each data symbol corresponding to the insertion position of the redundancy symbol in the data string to the next interleaving position next to the in-sequence interleaving position;
a syndrome calculator configured to calculate a syndrome for each of the M assigned data strings; and
an error locator configured to locate an error position and an error value from the syndrome of each interleave.

8. The error corrector of claim 1, wherein the data string received by the ECC encoder is a run length limited (RLL) encoded data string.

9. A data storage device, comprising:
an ECC encoder configured to assign data symbols of a data string to interleaving positions of M interleaves in interleaving sequence in order to generate M interleaved data strings, to create redundancy symbols for each of the M interleaved data strings, to insert the created redundancy symbols not corresponding to the M interleaved data strings that the redundancy symbols were created into the data string by every N data symbols of the data string, and to create ECC encoded data, wherein M is greater than or equal to 2 and N is also greater than or equal to 2;
a recorder configured to record the ECC encoded data from the ECC encoder in a recording medium;
a reader configured to read the data string inserted with the redundancy symbols from the recording medium; and
an ECC decoder configured to assign the data symbols of the read data string inserted with the redundancy symbols to interleaving positions of M interleaves in order to generate M assigned data strings and correct errors in each of the M assigned data strings, using the redundancy symbols of the assigned data string,
wherein the ECC encoder is further configured to assign each data symbol of the data string that corresponds to an insertion position of the created redundancy symbols not corresponding to the M interleaved data strings that the redundancy symbols were created in the data string to a next interleaving position next to an in-sequence interleaving position of the data symbol, the in-sequence interleaving position being in accordance with the interleaving sequence, and to create the redundancy symbols for each interleaved data string.

10. The data storage device of claim 9, wherein the ECC decoder is further configured to sort the data string inserted with the redundancy symbols in order to generate the data string and the redundancy symbols, to assign each data symbol corresponding to the insertion position of the redundancy symbol to the next interleaving position.

11. The data storage device of claim 9, wherein the greatest common divisor of M and N is “1”.

12. The data storage device of claim 9, wherein the ECC encoder comprises:
a memory configured to store the data string;
an ECC generator configured to assign the data symbols of the data string to the interleaving positions of the M interleaves and to create the redundancy symbols for each of the M interleaved data strings; and
a creator configured to insert the created redundancy symbols not corresponding to the M interleaved data strings that the redundancy symbols were created into the data string every N data symbols of the data string in the memory and to create the ECC encoded data.

13. The data storage device of claim 12, wherein the ECC generator comprises an interleaver configured to assign the data symbols of the data string to the interleaving positions of the M interleaves.

14. The data storage device of claim 10, wherein the ECC decoder comprises:
a sorter configured to sort the data string inserted with the redundancy symbols in order to generate the data string and the redundancy symbols;
a memory configured to store the sorted data string; and
an ECC corrector configured to assign each data symbol corresponding to the insertion position of the redundancy symbol of the sorted data string to the next interleaving position next to the in-sequence interleaving position and to correct errors in each of the M assigned data strings in the memory using the redundancy symbols of the assigned data string.

15. The data storage device of claim 14, wherein the ECC corrector comprises:
an interleaver configured to assign the data symbols of the data string to the interleaving positions of the M interleaves and to assign each data symbol corresponding to the insertion position of the redundancy symbol in the data string to the next interleaving position next to the in-sequence interleaving position;
a syndrome calculator configured to calculate a syndrome for each of the M assigned interleaved data strings; and
an error locator configured to locate an error position and an error value from the syndrome of each interleave.

16. The data storage device of claim 9, further comprising an RLL encoder configured to RLL encode the data string and to transmit the RLL encoded data string to the ECC encoder.

17. The data storage device of claim 16, further comprising an RLL decoder configured to RLL decode the data string with regards to the error correction.

18. The data storage device of claim 9 further comprise a head comprising the writer configured to write data in the storage medium and the reader configured to read data from the storage medium.
